(19) United States
(12) Patent Application Publication
(10) Pub. No.: US 2024/0413579 A1
(43) Pub. Date: Dec. 12, 2024

(54) SECURING DEVICE HAVING AN IDENTIFYING FEATURE AND A CONCEALING FEATURE WHICH ARE PLACED IN AN ABSOLUTE POSITION RELATIVE TO ONE ANOTHER

(71) Applicant: Lisa Dräxlmaier GmbH, Vilsbiburg (DE)

(72) Inventors: Stefan WIMMER, Hohenthann (DE); Sebastian WILHELM, Schmelz (DE); Franziska NEUMAYER, Geisenhausen (DE)

(73) Assignee: Lisa Dräxlmaier GmbH, Vilsbiburg (DE)

(21) Appl. No.: 18/735,625

(22) Filed: Jun. 6, 2024

(30) Foreign Application Priority Data
Jun. 6, 2023 (DE) 102023114789.7

(51) Int. Cl. H01R 13/641; H01R 13/629

(52) U.S. Cl. CPC H01R 13/641; H01R 13/62933

(57) ABSTRACT

A securing device for securing the locking of a locking element, including a locking element, which can be moved from a first locking position into a second locking position. The locking element produces locking in the second locking position. The securing device further includes a flap element including an identifying feature and a concealing feature, which are placed in an absolute position relative to one another on the flap element. The flap element may be moved from a first flap position, in which the concealing feature conceals the identifying feature, into a second flap position, in which the identifying feature is visible, when the locking element is in the second locking position. The identifying feature indicates an item of information.

### CROSS-REFERENCE TO RELATED APPLICATIONS

This application claims priority to and the benefit of DE 10 2023 114 789.7 filed on Jun. 6, 2023. The disclosure of the above-referenced application is incorporated herein by reference.

### FIELD

The present disclosure relates to a securing device to secure the locking of a locking element.

### BACKGROUND

The statements in this section merely provide background information related to the present disclosure and may not constitute prior art.

CPA (connector position assurance) systems are intended to inhibit a connector housing latched to a mating connector housing from being inadvertently detached from the mating connector housing, as can happen for example due to vibrations, temperature-related expansion or shrinkage, pulling on a cable accommodated in the connector housing, or other mechanical effects. For this, the CPA system is responsible for locking the connector to its mating connector, as the last element to be operated. In order to provide secure locking here, it is desired for the final state of the locking to be detected by virtue of a scannable element and for this element to be readable when the CPA system is finally closed.

### SUMMARY

This section provides a general summary of the disclosure and is not a comprehensive disclosure of its full scope or all of its features.

The present disclosure relates to a securing device having an identifying feature and a concealing feature, which are placed in an absolute position relative to one another. The securing device serves to secure the locking of a locking element or for “connector position assurance (CPA)” and can be used to secure the locking of a connector housing to a mating connector housing. In particular, the present disclosure relates to a CPA system having a scannable element, which conceals itself.

The present disclosure provides a suitable device which makes it possible to reliably discern if locking is present or not, in particular for connectors for which CPA locking is desired.

The connector may have a high degree of automation in terms of production and fabrication that makes the use of a scannable element desired as an assurance function. The present disclosure presented here relates to a securing device having an identifying feature and a concealing feature, wherein the identifying feature can be used as scannable element, in order to thus provide reliable assurance of the connector mounting and make it possible to scan the plug system in the assembled state. Usually, the connector has already been produced and is mounted. This mounting process can be assured here. The present disclosure can be applied to various plug systems and can be easily adapted from one plug system to another plug system.

The present disclosure provides a concealing feature and an identifying feature that are on the same component and are always in an absolute position relative to one another. The concealing is produced in that the element itself is concealed owing to a flap mechanism. This flap mechanism is controlled via the CPA system. Only once the clip has been actuated is the CPA system enabled and can be locked. After locking, the CPA system releases the flap mechanism and the additional element can be operated. The identifying feature is thus “exposed” and can be detected.

The basic function here is a concealing feature and an identifying feature, which are always in an absolute position relative to one another. Both features or elements are placed absolutely relative to one another. A relative movement takes place only between the concealing feature and, for example, the connector housing or between the identifying feature and, for example, the connector housing.

The present disclosure provides a scannable element to scan the identifying feature, which can serve as assurance function in the production and fabrication of connectors with a high degree of automation.

According to a first aspect, the present disclosure provides a securing device for securing the locking of a locking element, wherein the securing device includes the following: a locking element, which can be moved from a first locking position into a second locking position, wherein the locking element produces locking in the second locking position; and a flap element having an identifying feature and a concealing feature, which are placed in an absolute position relative to one another on the flap element, wherein the flap element can be moved from a first flap position, in which the concealing feature conceals the identifying feature, into a second flap position, in which the identifying feature is visible, when the locking element is in the second locking position, wherein the identifying feature indicates an item of information. This item of information may contain information about the locking by the locking element, but it may also be any other type of information. The locking can already be discerned by discerning the item of information. If the item of information is not discerned, locking cannot be discerned.

The absolute position of the identifying feature and the concealing feature on the flap element means in this case that a coordinate system which defines the identifying feature and a coordinate system which defines the concealing feature are in an absolute position relative to one another on the flap element, in one example on the front side and the back side of the flap element.

Such a securing device affords the technical advantage that it is possible to securely and reliably discern locking. The identifying feature can be discerned and detected, for example via a scannable element, with the result that it is possible to reliably automatically discern the position of the locking element. This also makes it possible to in particular automatically detect the state of connectors for which CPA locking is desired. The securing device thus meets the standards for CPA locking.

According to an example of the securing device, the concealing feature and the identifying feature are placed in fixed positions on the flap element, with the result that a relative position of the concealing feature with respect to the identifying feature does not change when the flap element is moved. This corresponds to the absolute position described above of the identifying feature and the concealing feature relative to one another.

This affords the technical advantage that a relative change in position of the concealing feature with respect to the identifying feature cannot occur. The absolute position of the identifying feature and the concealing feature cannot be changed. By folding back the flap element, the relative position in relation to a connector housing is changed, as described later on. This change in position in the overall system can cause concealment or exposure. It is therefore possible to reliably establish the position of the flap element and thus of the locking state of the locking element.

According to an example of the securing device, the flap element has a first main side and a second main side facing away from the first main side, wherein the concealing feature is placed on the first main side of the flap element or on at least a part of the first main side; and wherein the concealing feature is placed on the second main side of the flap element or on at least a part of the second main side.

This affords the technical advantage that the concealing feature and the identifying feature are placed on opposite sides of the flap element and folding back the flap element makes either one feature or the other feature detectable, with the result that it is possible to clearly discern the state of the flap element and thus the state of the locking element.

According to an example of the securing device, the concealing feature has a first geometric structure; and the identifying feature has a second geometric structure, which differs from the first geometric structure.

This affords the technical advantage that, owing to the different geometric structures, it is possible to clearly discern the position of the flap element and thus the position of the locking element.

According to an example of the securing device, the identifying feature is discernible, for example can be read via a reader, when the identifying feature is not concealed by the concealing feature.

This affords the technical advantage that the state of the locking element can be determined securely and reliably via a reader, for example a scanner. This makes it possible to efficiently assure automated mounting of plug systems.

According to an example of the securing device, the identifying feature is visible to the eye when the identifying feature is not concealed by the concealing feature.

This affords the technical advantage that the identifying feature can be discerned by the operator, but also is detectable automatically via a reader.

According to an example of the securing device, the securing device includes a rotary bearing for mounting the flap element, wherein the rotary bearing is designed to rotate the flap element into the first flap position and into the second flap position.

This affords the technical advantage that, via the rotary bearing, the flap element can be easily moved from the first flap position into the second flap position.

According to an example of the securing device, the securing device is designed to perform connector position assurance (CPA) to secure the locking of a connector housing to a mating connector housing.

This affords the technical advantage that the state of the CPA system can be reliably detected by virtue of a scannable element, which is readable only when the CPA system is finally closed.

According to an example of the securing device, the securing device also includes: a clamping element for clamping a connector housing into a mating connector housing, wherein the clamping element can be moved from an open clamping-element position, in which the connector housing can be inserted into the mating connector housing, into a closed clamping-element position, in which the connector housing is fastened to the mating connector housing with electrical contact; wherein the locking element is placed on the clamping element and designed to lock or to unlock the clamping element. As described above, the identifying feature indicates an item of information, for example an item of information about the locking or non-locking of the clamping element by the locking element. Any other item of information can also be indicated. Discernment of the locking is determined by discernment of the item of information.

This affords the technical advantage that the identifying feature can reliably indicate the locking of the clamping element, for example a clip, so that the state of the clamping element can be efficiently detected via a scannable element.

According to an example of the securing device, in the closed clamping-element position, the locking element can be moved from the first locking position into the second locking position and is designed, in the second locking position, to lock the clamping element in the closed clamping-element position and, in the first locking position, to unlock the clamping element for a movement into the open clamping-element position.

This affords the technical advantage that a secure connection of the connector housing to the mating connector housing via the clamping element is provided. The securing device thus meets the standards for CPA locking.

According to a second aspect, the present disclosure provides a plug connection having a connector housing and a mating connector housing, which are connected to one another and secured by a securing device according to the first aspect.

According to a third aspect, the present disclosure provides a securing system including a securing device according to the first aspect and a reader, wherein the reader is designed to detect the identifying feature when the flap element is in the second flap position, in order to discern locking.

According to an example of the securing system, the reader is designed to detect the identifying feature only when the flap element is in the second flap position and thus the locking element is in the second locking position and to detect correct locking only in this position.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a schematic illustration of the states of a securing device according to the present disclosure;

FIG. 2A shows a perspective view of a flap element according to the present disclosure in the first flap position, in which the concealing feature conceals the identifying feature;

FIG. 2B shows a perspective view of the flap element from FIG. 2A in the second flap position, in which the identifying feature is visible;

FIG. 3A shows a perspective view of a flap device according to the present disclosure, with the flap element in the first flap position, in which the concealing feature conceals the identifying feature;

FIG. 3B shows a perspective view of the flap device from FIG. 3A in an intermediate position 126 between the first and the second flap position, in which the concealing feature 123 conceals the identifying feature, wherein coordinate systems K1, K2, K3 for defining the absolute position are illustrated;

FIG. 3C shows a perspective view of the flap device from FIG. 3A in the second flap position, in which the identifying feature is visible;

FIG. 4A shows a perspective view of a securing device including a locking element, a flap element, and a clamping element in a partially open clamping-clip position; and

FIG. 4B shows a perspective view of a securing device including a locking element, a flap element, and a clamping element in a closed clamping-clip position.

The figures are merely schematic illustrations and serve only to explain the invention. Elements that are the same or have the same effect are provided with the same reference signs throughout.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the detailed description that follows, reference is made to the accompanying drawings, which form a part thereof and which show, as an illustration, specific examples in which the present disclosure can be carried out. It goes without saying that other examples can also be used and structural or logical changes can be made without departing from the concept of the present disclosure. The detailed description that follows should therefore not be understood in a restrictive sense. It also goes without saying that the features of the various examples described herein can be combined with one another unless specifically stated otherwise.

The aspects and examples are described with reference to the drawings, wherein reference signs that are the same generally relate to the same elements. Numerous specific details are set out for the purposes of explanation in the description that follows in order to provide an in-depth understanding of one or more aspects of the present disclosure. However, it may be obvious to a person skilled in the art that one or more aspects or examples can be implemented with a lesser degree of the specific details. In other cases, known structures and elements are illustrated in a schematic form in order to make it easier to describe one or more aspects or examples. It goes without saying that other examples can be used and structural or logical changes can be made without departing from the concept of the present disclosure.

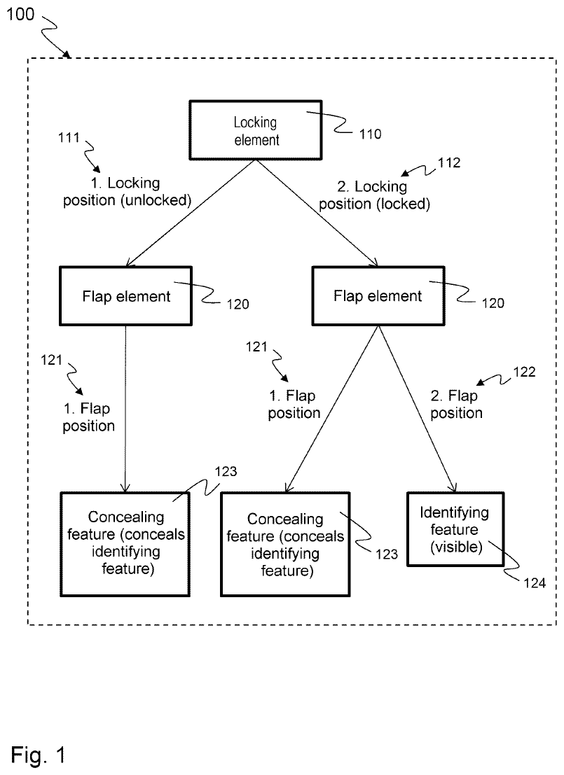

FIG. 1 shows a schematic illustration of the states of a securing device 100 according to the present disclosure.

The securing device 100 serves to secure the locking of a locking element 110. The securing device 100 includes a locking element 110 and a flap element 120.

The locking element 110 can be moved from a first locking position 111 into a second locking position 112 and produces locking in the second locking position 112.

The flap element 120 has an identifying feature 124 and a concealing feature 123, which are placed in an absolute position relative to one another on the flap element 120. The flap element 120 can be moved from a first flap position 121, in which the concealing feature 123 conceals the identifying feature 124, into a second flap position 122, in which the identifying feature 124 is visible, when the locking element 110 is in the second locking position 112.

Here, the identifying feature 124 indicates an item of information. This item of information may include, for example, an item of information about locking or non-locking by the locking element 110. It may, however, also be any other type of information.

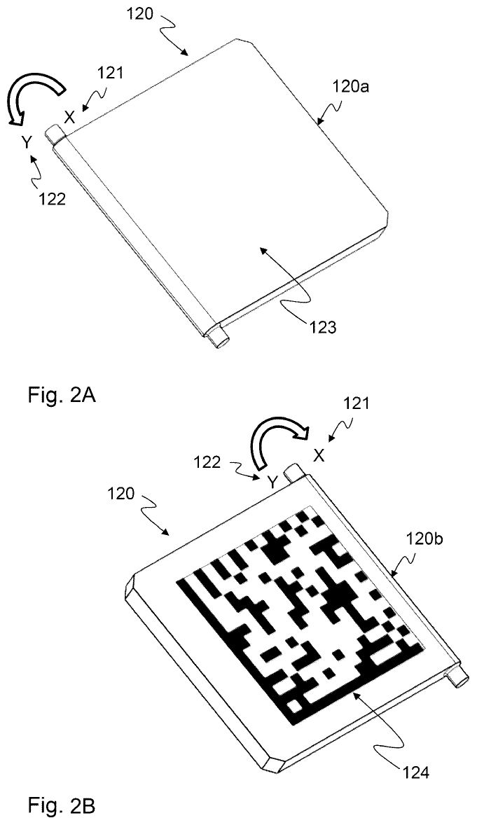

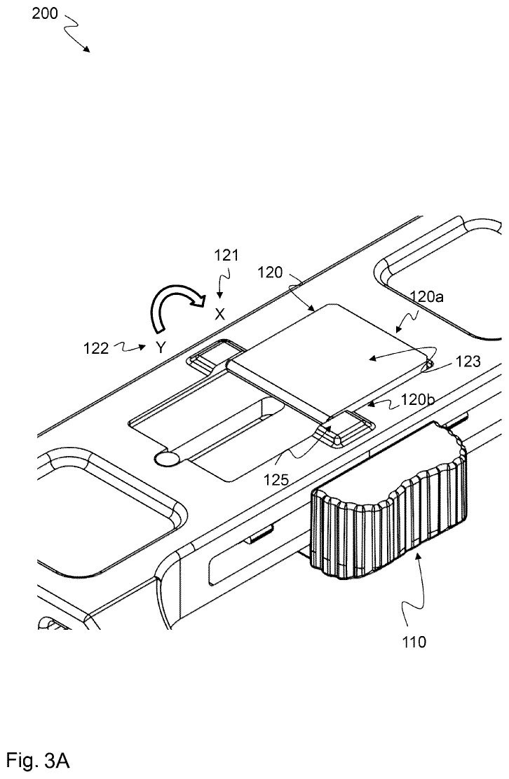

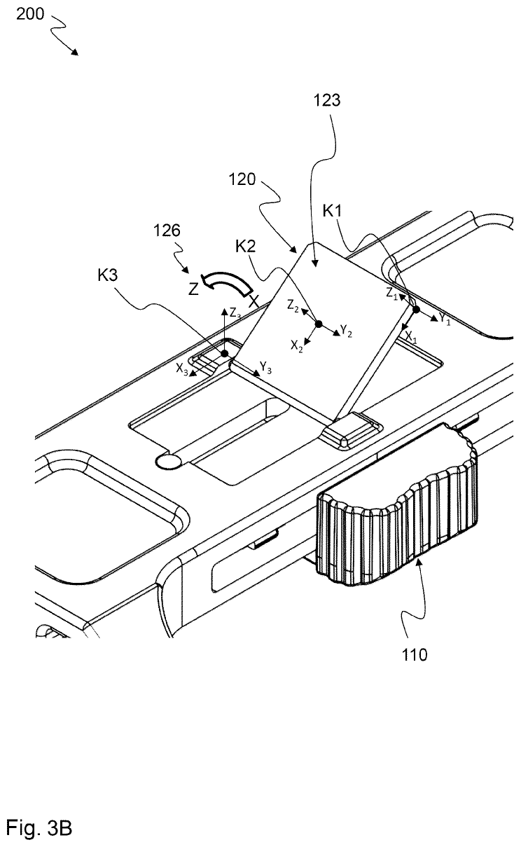

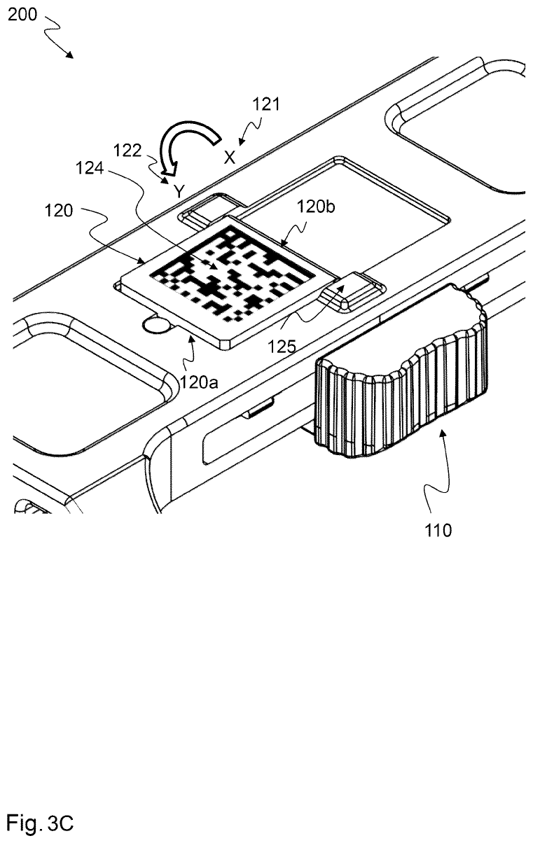

Examples of the flap element 120 having a concealing feature 123 and an identifying feature 124 are described in more detail in relation to FIGS. 2A, 2B, 3A, 3B and 3C.

FIGS. 2A and 2B show perspective views of a flap element 120 according to the present disclosure. In FIG. 2A, the flap element 120 is in the first flap position 121, in which the concealing feature 123 conceals the identifying feature 124. In FIG. 2B, the flap element 120 is in the second flap position 122, in which the identifying feature 124 is visible.

As mentioned, FIGS. 2A and 2B show the flap element 120 having the concealing feature 123 and the identifying feature 124. The concealing feature 123 is illustrated in this case as a white surface (FIG. 2A); the indicator feature 124 is illustrated in this case as a surface with a visible symbol, here in FIG. 2B using the example of a QR code. The white surface and the surface with the QR code are only for illustration purposes. Other symbols can similarly be used as concealing feature and identifying feature.

The flap element 120 has an identifying feature 124 (see FIG. 2B) and a concealing feature 123 (see FIG. 2A). The flap element 120 can be moved from a first flap position 121, also denoted by the letter “X”, as illustrated in FIG. 2A, in which the concealing feature 123 conceals the identifying feature 124, into a second flap position 122, also denoted by the letter “Y”, as illustrated in FIG. 2B, in which the identifying feature 124 is visible. The flap element is placed such that it can be moved into the second flap position 122 only when the locking element 110 is in the second locking position 112, and thus produces locking. The identifying feature 124 then indicates locking by the locking element 110.

The identifying feature 124 and the concealing feature 123 are placed in an absolute position relative to one another on the flap element 120, as already described above. This also means that the concealing feature 123 and the identifying feature 124 are placed in fixed positions on the flap element 120, with the result that the absolute positions of the concealing feature 123 and the identifying feature 124 on the flap element 120 relative to one another and also a relative position of the concealing feature 123 with respect to the identifying feature 124 do not change when the flap element 120 is moved.

The flap element 120 has a first main side 120a (shown in FIG. 2A) and a second main side 120b facing away from the first main side 120a (shown in FIG. 2B).

The concealing feature 123 is placed on the first main side 120a of the flap element 120 or on at least a part of the first main side 120a; and the identifying feature 124 is placed on the second main side 120b of the flap element 120 or on at least a part of the second main side 120b. It goes without saying that this placement can also be reversed.

The concealing feature 123 may have a first geometric structure, for example a white side, as illustrated in FIG. 2A. As shown in FIG. 2B, the identifying feature 124 has a second geometric structure, which differs from the first geometric structure. The second geometric structure is illustrated here by way of example as a QR code, but the second geometric structure may also be any other geometric structure, for example a symbol, pictogram, QR code, barcode, etc.

As mentioned, in this example of FIGS. 2A and 2B, the first geometric structure is a white side and the second geometric structure is a QR code. It goes without saying that any other geometric structure or shape can be used. For example, the first geometric structure may be a triangle and the second geometric structure may be a square, or other geometric shapes that differ from one another can be used.

The identifying feature 124 is discernible, for example readable and discernible via a reader or another scanner, when the identifying feature 124 is not concealed by the concealing feature 123. Specifically, when the flap element 120 is in the second flap position 122, as illustrated in FIG. 2B, the identifying feature 124 is visible and can be discerned, for example read by the reader, for example a scannable element or a photosensor.

As illustrated in FIG. 2B, the identifying feature 124 is visible to the eye when the identifying feature 124 is not concealed by the concealing feature 123.

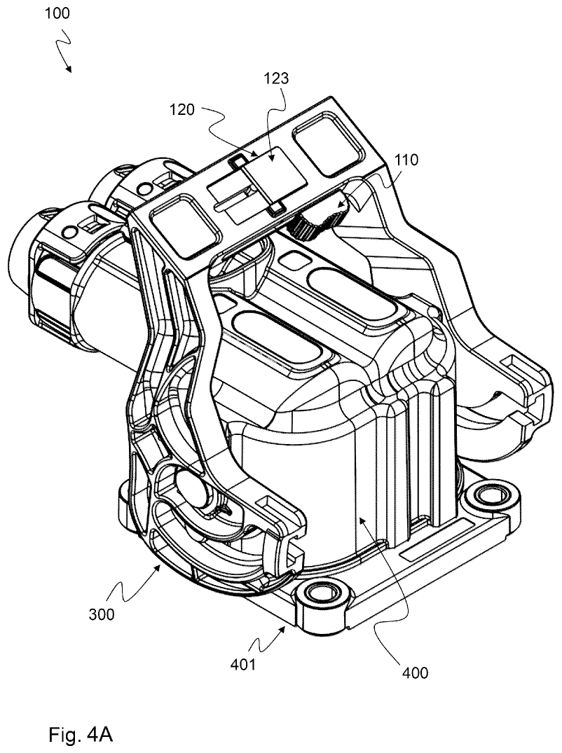

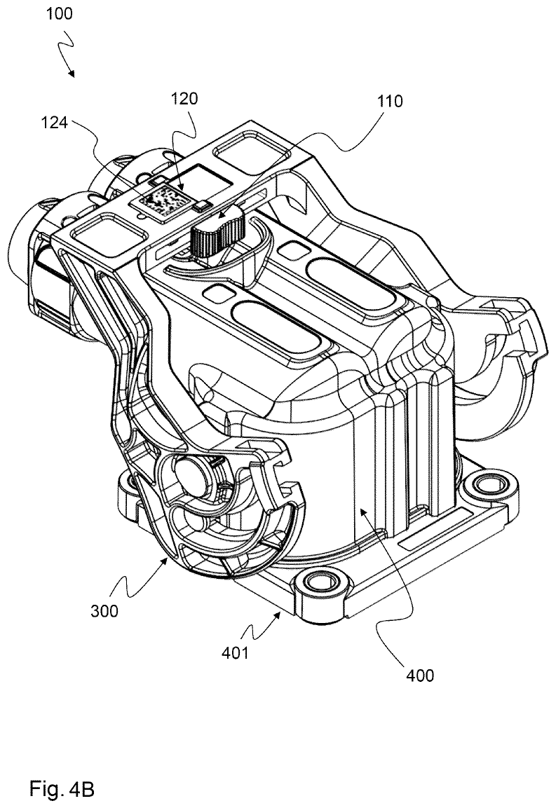

FIGS. 3A, 3B and 3C show perspective views of a flap device 200 according to the present disclosure having a flap element 120, as illustrated in FIGS. 2A and 2B. In FIG. 2A, the flap element 120 is in the first flap position 121, in which the concealing feature 123 conceals the identifying feature 124, analogously to FIG. 2A. In FIG. 3C, the flap element 120 is in the second flap position 122, in which the identifying feature 124 is visible, analogously to FIG. 2B. In FIG. 3B, the flap element 120 is in an intermediate position 126 (represented by the letter “Z”) between the first and the second flap position, in which intermediate position the concealing feature 123 conceals the identifying feature 124. The flap device 200 described here may be used in a securing device 100, for example a securing device 100 as described in FIG. 1 or in FIGS. 4A and 4B.

In particular, FIGS. 3A, 3B and 3C show the movement sequence of the flap element 120. In the 0° position (FIG. 3A), the surface with the QR code is concealed by the white surface. The element 120 conceals itself, as it were. After the CPA system has been actuated (only the flap mechanism is schematically illustrated here), the flap element 120 can be rotated and the QR code (identifying feature 124) is visible in the final 180° position (FIG. 3C).

It is evident here that in any position of the element 120, also at 30° (see FIG. 3B), both features 123, 124 are always in an absolute position or location relative to one another. A relative movement between them does not take place.

As mentioned, the flap element 120 has an identifying feature 124 (see FIG. 3C) and a concealing feature 123 (see FIGS. 3A and 3B). The flap element 120 can be moved from a first flap position 121, as illustrated in FIG. 3A, in which the concealing feature 123 conceals the identifying feature 124, via an intermediate position 126, as illustrated in FIG. 3B, into a second flap position 122, as illustrated in FIG. 3C, in which the identifying feature 124 is visible. The flap element 120 is placed such that it can be moved into the second flap position 122 only when the locking element 110 is in the second locking position 112, and thus produces locking. The identifying feature 124 then indicates an item of information, in this case as an example the QR code. The item of information can indicate locking by the locking element 110, for example when the QR code is being read out. Any other information can be used here according to the present disclosure instead of the QR code.

The flap device 200 includes a rotary bearing 125 for mounting the flap element 120. The rotary bearing 125 is designed to rotate the flap element 120 into the first flap position 121 and into the second flap position 122 and into intermediate positions 126 between the first flap position 121 and the second flap position 122.

The rotary bearing 125 is placed on a plate, which forms a boundary or a stop for the rotational movement of the flap element 120 from the first flap position 121 into the second flap position 122. The flap element 120 is also in the form of a plate, which on one side has a hinge which is inserted in the rotary bearing 125.

The concealing feature 123 and the identifying feature 124 are placed in absolute or fixed positions on the flap element 120, with the result that a relative position of the concealing feature 123 with respect to the identifying feature 124 does not change when the flap element 120 is moved.

This is illustrated on the basis of the coordinate systems K1, K2 and K3 in FIG. 3B. K1 denotes the coordinate system of the identifying feature 124; K2 denotes the coordinate system of the concealing feature 123; and K3 denotes the coordinate system of the point of rotation or the rotary bearing 125. The two coordinate systems K1 and K2 are absolute in relation to one another, since they are placed on the two main sides 120a, 120b of the flap element 120. The two coordinate systems K1 and K2 are relative to the coordinate system K3, since K3 is on the point of rotation or the rotary bearing 125 of the flap element 120 and does not change when the flap element 120 is rotated, by contrast to the coordinate systems K1 and K2 which change with a rotation in the same way with respect to the rotary bearing 125 or the point of rotation.

As already described above in relation to FIGS. 2A and 2B, the flap element 120 has a first main side 120a (shown in FIG. 2A) and a second main side 120b facing away from the first main side 120a (shown in FIG. 2B).

The concealing feature 123 is placed on the first main side 120a of the flap element 120 or on at least a part of the first main side 120a (here in the middle of the first main side 120a); and the identifying feature 124 is placed on the second main side 120b of the flap element 120 or on at least a part of the second main side 120b (here in the middle of the second main side 120b). It goes without saying that this placement can also be reversed.

The design of the flap elements 120 corresponds to the flap element 120 as already described above in relation to FIGS. 2A and 2B.

The securing device 100 is designed to perform connector position assurance (CPA) to secure the locking of a connector housing 400 to a mating connector housing 401, for example according to the example of FIGS. 4A and 4B.

The securing device 100 and a reader make it possible to implement a securing system which can reliably determine the state of the locking element 110 and transfer this state, for example to a controller, for further processing. Such a securing system includes a securing device 100 as described above and a reader. The reader is designed to detect the identifying feature 124 when the flap element 120 is in the second flap position 122, in order to discern locking.

The reader may be designed, for example, to detect the identifying feature 124 only when the flap element 120 is in the second flap position 122 and thus the locking element 110 is in the second locking position 112 and to detect correct locking only in this position.

The reader may forward the detected information to a controller, which then can indicate a fault and take corresponding steps to control the production or fabrication process.

FIGS. 4A and 4B show 3D illustrations of a securing device 100 including a locking element 110, a flap element 120 and a clamping element 300. FIG. 4A illustrates the clamping element 300 in an open clamping-clip position, whereas the clamping element 300 is illustrated in a closed clamping-clip position in FIG. 4B. The securing device 100 includes a flap device 200 as described above in relation to FIGS. 3A to 3C and set out in more detail below.

The securing device 100 is designed to perform connector position assurance (CPA) to secure the locking of a connector housing 400 to a mating connector housing 401.

In addition to the locking element 110 and flap element 120 that are already described above, the securing device 100 also includes a clamping element 300, for example a clamping clip, for clamping the connector housing 400 into the mating connector housing 401.

The clamping element 300 can be moved from an open clamping-element position (see FIG. 4A), in which the connector housing 400 can be inserted into the mating connector housing 401, into a closed clamping-element position (see FIG. 4B), in which the connector housing 400 is fastened to the mating connector housing 401 with electrical contact.

The locking element 110 is placed on the clamping element 300 and is designed to lock or to unlock the clamping element 300.

The identifying feature 124 indicates an item of information, for example an item of information about locking or non-locking of the clamping element 300 by the locking element 110. In FIG. 4A, no identifying feature 124 but only the concealing feature 123 is indicated, whereas in FIG. 4B the identifying feature 124 is indicated.

In the closed clamping-element position, the locking element 110 can be moved from the first locking position 111 into the second locking position 112. The locking element 110 is designed, in the second locking position 112, to lock the clamping element 300 in the closed clamping-element position (see FIG. 4B) and, in the first locking position 111, to unlock the clamping element 300 for a movement into the open clamping-element position (see FIG. 4A).

When the locking element 110 is being moved into the second locking position 112, the flap element 120 can be folded back from the first flap position 121 into the second flap position 122, with the result that the identifying feature 124 is visible and discernible. It may then be detected, for example by virtue of a scannable element.

If the locking element 110 is in the first locking position 111, the flap element 120 is locked in the first flap position 121 and cannot be folded back from the first flap position 121 into the second flap position 122, with the result that the concealing feature 123 conceals the identifying feature 124 and thus the identifying feature 124 is not discernible and cannot be detected, for example by virtue of a scannable element.

FIGS. 4A and 4B thus also show a plug connection having a connector housing 400 and a mating connector housing 401, which are connected to one another and secured by the securing device 100 as described above.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A securing device for securing a locking of a locking element, comprising:
the locking element configured to move from a first locking position into a second locking position, the locking element configured to lock in the second locking position; and
a flap element including an identifying feature and a concealing feature, the identifying feature and the concealing feature are placed in a position relative to one another on the flap element, the flap element is configured to move from a first flap position, in which the concealing feature conceals the identifying feature, into a second flap position, in which the identifying feature is visible in the second locking position, and the identifying feature indicates an item of information.

2. The securing device according to claim 1, wherein the concealing feature and the identifying feature are placed in fixed positions on the flap element such that a relative position of the concealing feature with respect to the identifying feature does not change when the flap element is moved.

3. The securing device according to claim 1, wherein the flap element includes a first main side and a second main side facing away from the first main side, the concealing feature is placed on at least a part of the first main side of the flap element and the concealing feature is placed on at least a part of the second main side of the flap element.

4. The securing device according to claim 1, wherein the concealing feature has a first geometric structure, the identifying feature has a second geometric structure, and the second geometric structure differs from the first geometric structure.

5. The securing device according to claim 1, wherein the identifying feature is discernible when the identifying feature is not concealed by the concealing feature.

6. The securing device according to claim 1, wherein the identifying feature is visible when the identifying feature is not concealed by the concealing feature.

7. The securing device according to claim 1, further comprising:
a rotary bearing configured to mount the flap element, and the rotary bearing is configured to rotate the flap element into the first flap position and into the second flap position.

8. The securing device according to claim 1, wherein the securing device is configured to perform connector position assurance (CPA) to secure a lock between a connector housing and a mating connector housing.

9. The securing device according to claim 1, further comprising:
a clamping element configured to clamp a connector housing into a mating connector housing, the clamping element configured to move from an open clamping-element position, in which the connector housing is insertable into the mating connector housing, into a closed clamping-element position, in which the connector housing is configured to be fastened to the mating connector housing with electrical contact; and
the locking element is placed on the clamping element and configured to lock or to unlock the clamping element.

10. The securing device according to claim 9, wherein, in the closed clamping-element position, the locking element is configured to move from the first locking position into the second locking position and is configured, in the second locking position, to lock the clamping element in the closed clamping-element position and, in the first locking position, to unlock the clamping element for a movement into the open clamping-element position.
